(19) United States
(12) Patent Application Publication
(10) Pub. No.: US 2022/0006042 A1
(43) Pub. Date: Jan. 6, 2022

(54) DISPLAY PANEL AND MANUFACTURING METHOD THEREOF

(71) Applicant: SHENZHEN CHINA STAR OPTOELECTRONICS SEMICONDUTOR DISPLAY TECHNOLOGY CO., LTD., Shenzhen (CN)

(72) Inventor: Jia TANG, Shenzhen (CN)

(73) Assignee: SHENZHEN CHINA STAR OPTOELECTRONICS SEMICONDUTOR DISPLAY TECHNOLOGY CO., LTD., Shenzhen (CN)

(21) Appl. No.: 16/755,578

(22) PCT Filed: Apr. 2, 2020
(86) PCT No.: PCT/CN2020/082980

§ 371 Date: Apr. 12, 2020

(30) Foreign Application Priority Data
Feb. 19, 2020 (CN) 202010102587.2

(51) Int. Cl. H01L 51/52; H01L 27/32; H01L 51/56

(52) U.S. Cl. CPC H01L 51/5228; H01L 27/3272; H01L 2227/323; H01L 51/56; H01L 27/322

(57) ABSTRACT

A display panel and a manufacturing method thereof are provided. The display panel includes an array substrate, a light-emitting device layer, and a color filter layer. The color filter layer includes a plurality of color resists, a light-shielding layer arranged between two adjacent color resists, and a plurality of auxiliary electrodes arranged on the light-shielding layer. The present application, through providing the auxiliary electrodes electrically connected to a cathode layer on the light-shielding layer and in cooperation with light-shielding units having different heights, reduces a voltage drop of an electrode close to a center of a display, thereby improving uniformity of display brightness and enhancing user's visual effect.

### FIELD OF INVENTION

The present application relates to the field of display, particularly to the field of display technologies, and in particular to a display panel and a manufacturing method thereof.

### BACKGROUND OF INVENTION

With improvement of living standards, white organic light-emitting diode (WOLED) or white organic light-emitting semiconductor display screens are more widely used in large-sized display screens.

In conventional art, when a large-sized WOLED display screen is in operation, as a cathode voltage drop of an electrode gradually increases, a technical problem of uneven display brightness is caused. The closer the problem is to a center region, the more severe it becomes, causing poor visual effect for users.

Therefore, a display panel and a manufacturing method thereof are urgently needed to solve the above technical problem.

### SUMMARY OF INVENTION

### Technical Problem

The present application provides a display panel and a manufacturing method thereof to solve the problem that in the conventional art, when a large-sized white organic light-emitting diode (WOLED) display screen is in operation, due to a cathode voltage drop of an electrode gradually increases, the technical problem of uneven display brightness is caused, and the closer it is to a center region, the more severe it becomes.

### Technical Solutions

To solve the above problems, the technical solutions provided in the present application are as follows.

A display panel, including an array substrate, a light-emitting device layer disposed on the array substrate, and a color filter layer disposed on the light-emitting device layer;

wherein the color filter layer includes a plurality of color resists, a light-shielding layer arranged between two adjacent color resists, and a plurality of auxiliary electrodes disposed on the light-shielding layer; and

wherein the auxiliary electrodes are electrically connected to a cathode layer of the light-emitting device layer.

In the display panel of the present application, a resistance value of one of the auxiliary electrodes close to a center of the display panel is less than a resistance value of one of the auxiliary electrodes away from the center of the display panel.

In the display panel of the present application, a contact area of one of the auxiliary electrodes close to the center of the display panel and the cathode layer is greater than a contact area of one of the auxiliary electrodes away from the center of the display panel and the cathode layer.

In the display panel of the present application, a density of the auxiliary electrodes close to the center of the display panel is greater than a density of the auxiliary electrodes away from the center of the display panel.

In the display panel of the present application, a thickness of each of the auxiliary electrodes close to the center of the display panel is less than a thickness of each of the auxiliary electrodes away from the center of the display panel.

In the display panel of the present application, the light-shielding layer further includes a first light-shielding unit and a second light-shielding unit arranged on the first light-shielding unit;

wherein the second light-shielding unit includes a plurality of second sub light-shielding units; and

wherein the auxiliary electrodes are arranged on the second sub light-shielding units, and a density of the second sub light-shielding units close to the center of the display panel is greater than a density of the second sub light-shielding units away from the center of the display panel.

In the display panel of the present application, the auxiliary electrodes are arranged on any of the first sub light-shielding units, and are arranged on the second sub light-shielding units.

In the display panel of the present application, a thickness of each of the color resists is greater than a thickness of the first light-shielding unit, and the color resists are overlapped on the first light-shielding unit.

In the display panel of the present application, a thickness of the light-shielding layer is greater than a thickness of each of the color resists, and the light-shielding layer is overlapped on the color resists.

In the display panel of the present application, a thickness of the light-shielding layer is equal to a thickness of each of the color resists.

In the display panel of the present application, material of the auxiliary electrodes is one of a transparent conductive film or a flexible electrode.

A method of manufacturing a display panel, including:

forming a light-emitting device layer on an array substrate;

forming a color filter layer on a first substrate, wherein the color filter layer includes a plurality of color resists, a light-shielding layer arranged between two adjacent color resists, and a plurality of auxiliary electrodes arranged on the light-shielding layer; and

aligning and bonding the color filter layer and the light-emitting device layer, wherein the auxiliary electrodes are electrically connected to a cathode layer of the light-emitting device layer.

In the manufacturing method of the display panel of the present application, a step of forming the light-shielding layer and the auxiliary electrodes includes:

forming a first light-shielding unit on the first substrate;

forming a second light-shielding unit on the first light-shielding unit; and

forming the auxiliary electrodes on the second light-shielding unit;

wherein the second light-shielding unit includes a plurality of second sub light-shielding units, and a density of the second sub light-shielding units close to a center of the display panel is greater than a density of the second sub light-shielding units away from the center of the display panel.

In the manufacturing method of the display panel of the present application, the auxiliary electrodes are arranged on any of the first sub light-shielding units, and are arranged on the second sub light-shielding units.

In the manufacturing method of the display panel of the present application, a thickness of each of the color resists is greater than a thickness of the first light-shielding unit, and the color resists are overlapped on the first light-shielding unit.

In the manufacturing method of the display panel of the present application, a resistance value of one of the auxiliary electrodes close to a center of the display panel is less than a resistance value of one of the auxiliary electrodes away from the center of the display panel.

In the manufacturing method of the display panel of the present application, a contact area of one of the auxiliary electrodes close to the center of the display panel and the cathode layer is greater than a contact area of one of the auxiliary electrodes away from the center of the display panel and the cathode layer.

In the manufacturing method of the display panel of the present application, a thickness of the light-shielding layer is greater than a thickness of each of the color resists, and the light-shielding layer is overlapped on the color resists.

In the manufacturing method of the display panel of the present application, a thickness of the light-shielding layer is equal to a thickness of each of the color resists.

In the manufacturing method of the display panel of the present application, material of the auxiliary electrodes is one of a transparent conductive film or a flexible electrode.

### Beneficial Effect

The present application, through providing auxiliary electrodes electrically connected to the cathode layer on the light-shielding layer and in cooperation with light-shielding units of different heights, reduces the voltage drop of the electrode close to the center of the display, thereby improving uniformity of display brightness and enhancing user's visual effect.

### BRIEF DESCRIPTION OF FIGURES

FIG. 1 is a schematic structural diagram of a first structure of a display panel of the present application.

FIG. 2 is a schematic structural diagram of a second structure of the display panel of the present application.

FIG. 3 is a schematic flowchart of a method of manufacturing the display panel of the present application.

### DETAILED DESCRIPTION OF EMBODIMENTS

The present application provides a display panel and a manufacturing method thereof. In order to make the purpose, technical solution, and effect of the present application clearer and more specific, the present application will be described in detail below with reference to the accompanying drawings and embodiments. It should be understood that the specific embodiments described herein are only used to explain the application, and are not used to limit the application.

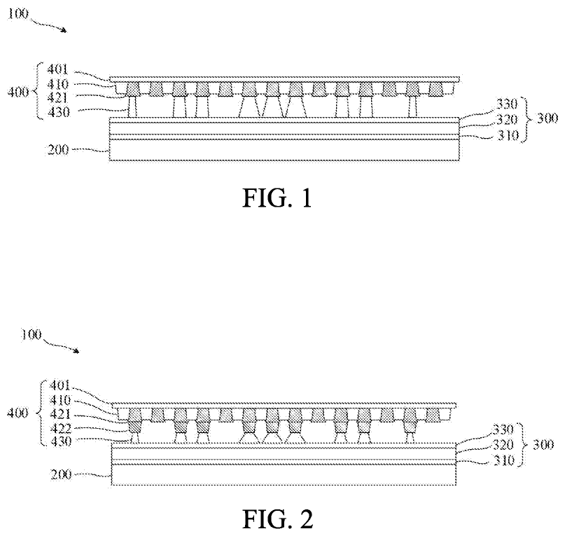

Please refer to FIG. 1 and FIG. 2, where a display panel 100 is provided in the present application. The display panel 100 includes an array substrate 200, a light-emitting device layer 300 disposed on the array substrate 200, and a color filter layer 400 disposed on the light-emitting device layer 300.

The color filter layer 400 includes a plurality of color resists 410, a light-shielding layer arranged between two adjacent color resists 410, and a plurality of auxiliary electrodes 430 disposed on the light-shielding layer.

The auxiliary electrodes 430 are electrically connected to a cathode layer 330 of the light-emitting device layer 300.

In the present application, the auxiliary electrodes 430 electrically connected to the cathode layer 330 are arranged on the light-shielding layer, and a plurality of light-shielding units having different heights are used to reduce a voltage drop of an electrode close to a center of the display panel, thereby improving uniformity of display brightness and enhancing user's visual effect.

The technical solution of the present application is described in combination with specific embodiments as follows.

### First Embodiment

Please refer to FIG. 1 and FIG. 2, the display panel 100 includes the array substrate 200, the light-emitting device layer 300 disposed on the array substrate 200, and the color filter layer 400 disposed on the light-emitting device layer 300.

The color filter layer 400 includes the color resists 410, the light-shielding layer arranged between two adjacent color resists 410, and the auxiliary electrodes 430 disposed on the light-shielding layer.

The auxiliary electrodes 430 are electrically connected to the cathode layer 330 of the light-emitting device layer 300.

In the present embodiment, the light-shielding layer is arranged continuously or at intervals.

In the present embodiment, a color of each of the color resists 410 is one of red, blue, or green, which is not limited herein.

In the present embodiment, any two of the auxiliary electrodes 430 are disposed with a spaced insulation.

In the present embodiment, light emitted from the light-emitting device layer 300 is white light.

In the present embodiment, the light-emitting device layer 300 includes an anode layer 310, a luminescent material layer 320, and the cathode layer 330. Please refer to FIG. 1 and FIG. 2 for details. The cathode layer 330 is away from the array substrate 200. The anode layer 310 is electrically connected to a source-drain layer of the array substrate 200.

In the present embodiment, a resistance value of one of the auxiliary electrodes 430 close to the center of the display panel 100 is less than a resistance value of one of the auxiliary electrodes 430 away from the center of the display panel 100. Generally, the more severe the voltage drop near the center of the display panel 100, the worse the display effect. The auxiliary electrodes 430 are further electrically connected to an external field, and an external field voltage is given to the auxiliary electrodes during display. The auxiliary electrodes 430 will also have resistance while increasing the voltage; hence, the resistance value of the auxiliary electrodes 430 closer to the center of the display panel 100 is smaller, so that a voltage drop can be better reduced, thereby improving display effect. The auxiliary electrodes 430 have an effect of reducing the voltage drop, as well as maintaining a step effect between the color filter layer 400 and the array substrate 200 to protect the display panel 100.

In the present embodiment, the light-shielding layer includes a first light-shielding unit. The first light-shielding unit includes a plurality of first sub light-shielding units 421.

In the present embodiment, a thickness of each of the auxiliary electrodes 430 close to the center of the display panel 100 is less than a thickness of each of the auxiliary electrodes 430 away from the center of the display panel 100. Correspondingly, a thickness of one of the first sub light-shielding units 421 corresponding to one of the auxiliary electrodes 430 close to the center of the display panel 100 is greater than a thickness of one of the first sub light-shielding units 421 corresponding to one of the auxiliary electrodes 430 away from the center of the display panel 100. A sum of the thicknesses of any set of one of the auxiliary electrodes 430 and its corresponding first sub light-shielding unit 421 is same, in a bid to ensure that the auxiliary electrodes 430 and the cathode layer 330 are electrically connected tightly. The more severe the voltage drop near the center of the display panel 100, the worse the display effect. Therefore, the closer to the center of the display panel 100, the smaller the thickness of the auxiliary electrodes 430, and the smaller the resistance value of the auxiliary electrodes 430, which can better reduce the voltage drop, thereby improving the display effect.

In the present embodiment, a contact area of one of the auxiliary electrodes 430 close to the center of the display panel 100 and the cathode layer 330 is greater than a contact area of one of the auxiliary electrodes 430 away from the center of the display panel 100 and the cathode layer 330. For details, please refer to FIG. 1 and FIG. 2. The more severe the voltage drop near the center of the display panel 100, the worse the display effect. Therefore, the closer to the center of the display panel 100, the greater the contact area of the auxiliary electrodes 430 and the cathode layer 330, and the smaller the resistance value of the auxiliary electrodes 430, which can better reduce the voltage drop, thereby improving the display effect.

In the present embodiment, a density of the auxiliary electrodes 430 arranged close to the center of the display panel 100 is greater than a density of the auxiliary electrodes 430 arranged away from the center of the display panel 100. The auxiliary electrodes 430 are not disposed in an edge region of the display panel 100. Please refer to FIG. 1 and FIG. 2 for details. The more severe the voltage drop near the center of the display panel 100, the worse the display effect. Therefore, the closer to the center of the display panel 100, the greater the density of the auxiliary electrodes 430, and the higher the voltage added to the center display area, which can better reduce the voltage drop can, thereby improving the display effect.

In the present embodiment, on a first cross-section, an area of one of the auxiliary electrodes 430 away from the color filter layer 400 is greater than an area of one of the auxiliary electrodes 430 close to the color filter layer 400. The first cross-section is parallel to the display panel 100. Please refer to FIG. 1 and FIG. 2 for details. By increasing the contact area between a single auxiliary electrode 430 and the cathode layer 330 and reducing the resistance value of the single auxiliary electrode 430, the voltage drop can be better reduced and the display effect is improved.

In the present embodiment, the light-shielding layer is made of a black matrix.

In the present embodiment, material of the auxiliary electrodes 430 is metal, or one of a transparent conductive film or a flexible electrode. Meanwhile, the flexible electrode not only improves the voltage drop close to the center of the display and improves the display effect, but can also better prevent the cathode layer 330 of the display panel 100 from being damaged when the display panel 100 is squeezed, thereby extending the service life of the display panel 100.

In the present embodiment, the auxiliary electrodes electrically connected to the cathode layer are arranged on the light-shielding layer, and the step effect between the color filter layer and the array substrate is achieved by using the auxiliary electrodes, thereby reducing the voltage drop of the electrode close to the center of the display, improving the uniformity of display brightness, and enhancing the user's visual effects.

### Second Embodiment

Please refer to FIG. 2, in which the present embodiment is same as or similar to the first embodiment, except that:

the light-shielding layer includes the first light-shielding unit and a second light-shielding unit arranged on the first light-shielding unit.

In the present embodiment, the first light-shielding unit includes the first sub light-shielding units 421. The second light-shielding unit includes a plurality of second sub light-shielding units 422. The auxiliary electrodes 430 are arranged on the second sub-shielding unit 422. A density of the second sub light-shielding units 422 arranged close to the center of the display panel 100 is greater than a density of the second sub light-shielding units 422 arranged away from the center of the display panel 100. Please refer to FIG. 2 for details. The second light-shielding units have a step effect between the color filter layer 400 and the array substrate 200 to protect the display panel 100, and can also be used as a carrier on a side of the auxiliary electrodes 430 to facilitate positioning of the auxiliary electrodes 430 as well as tight electrical connection of the auxiliary electrodes 430 to the cathode layer 330.

In the present embodiment, the auxiliary electrodes 430 are arranged on any of the first sub light-shielding units 421, and the auxiliary electrodes 430 are arranged on the second sub light-shielding units 422. The display panel can have more auxiliary electrodes 430 by adopting the above structure in a direction away from the center of the display, which has more compensation voltages with different voltages, thereby making the display more uniform.

In the present embodiment, the auxiliary electrodes 430 are arranged on any of the second sub light-shielding units 422. A part of the second sub light-shielding units 422 has no auxiliary electrode, which can provide more step differences and better protection of the display panel.

In the present embodiment, a thickness of the light-shielding layer is greater than a thickness of the color resists 410. The light-shielding layer and/or the first sub light-shielding units 421 and/or the second sub light-shielding units 422 are overlapped on the color resists 410. Please refer to FIG. 1 and FIG. 2 for details. While the light-shielding layer serves as a carrier for the auxiliary electrodes 430, this structural arrangement can also prevent the mixing of light of various colors, which improves purity of display color gamut and improves the display effect.

In the present embodiment, the thickness of the color resists 410 is greater than the thickness of the first light-shielding unit. The color resists 410 are overlapped on the first light-shielding unit. The thickness of the color resists 410 is less than a sum of the thicknesses of the first light-shielding unit and the second light-shielding unit. This structural arrangement can maximize the display aperture ratio, increase the display brightness, and improve the display effect.

In the present embodiment, the thickness of the color resists 410 is equal to the thickness of the first light-shielding unit. This structural arrangement can improve the display aperture ratio and increase the display brightness, while also preventing the mixing of light of various colors, thereby improving the purity of the display color gamut and improving the display effect.

In the present embodiment, a gate of the array substrate 200 can be a top-gate structure or a bottom-gate structure.

In the present embodiment, a manufacturing method of the array substrate 200 can adopt low-temperature polysilicon technology, metal oxide technology, or amorphous silicon technology, which is not limited herein.

In the present embodiment, luminescent material of the light-emitting device layer 300 of the display panel 100 can be processed by vapor-deposition or inkjet printing, which is not limited herein. A pixel definition layer formed by a vapor-deposition method of is a non-hydrophobic pixel definition layer, and the pixel definition layer formed by the inkjet printing method is a hydrophobic pixel definition layer.

In the present embodiment, the auxiliary electrodes 430 electrically connected to the cathode layer 330 are arranged on the light-shielding layer, and the light-shielding units having different heights are used to reduce the voltage drop of the electrode close to the center of the display panel, thereby improving uniformity of the display brightness and enhancing the user's visual effect.

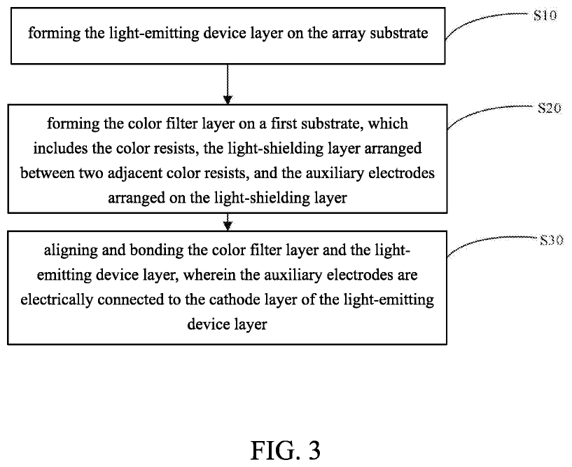

Referring to FIG. 1 to FIG. 3, the present application also proposes a method of manufacturing the display panel 100, including:

S10, forming the light-emitting device layer 300 on the array substrate 200;

S20, forming the color filter layer 400 on a first substrate 401, wherein the color filter layer includes the color resists 410, the light-shielding layer arranged between two adjacent color resists 410, and the auxiliary electrodes 430 arranged on the light-shielding layer; and

S30, aligning and bonding the color filter layer 400 and the light-emitting device layer 300, wherein the auxiliary electrodes 430 are electrically connected to the cathode layer 330 of the light-emitting device layer 300.

The present application, through providing auxiliary electrodes electrically connected to the cathode layer on the light-shielding layer and in cooperation with light-shielding units having different heights, reduces the voltage drop of the electrode close to the center of the display, thereby improving uniformity of the display brightness and enhancing the user's visual effect.

The technical solution of the present application is described in combination with specific embodiments as follows.

### Third Embodiment

Please refer to FIG. 1 to FIG. 3. The manufacturing method of the display panel 100 includes steps described below.

S10, forming the light-emitting device layer 300 on the array substrate 200.

In the present embodiment, the steps before forming the light-emitting device layer 300 on the array substrate 200 include:

sequentially forming a buffer layer, an active layer, a first insulating layer, a gate layer, a source-drain layer, and a second insulating layer on a second substrate; or

sequentially forming a buffer layer, a gate layer, a first insulating layer, an active layer, a source-drain layer, and a second insulating layer on a second substrate.

In the present embodiment, the manufacturing method of the array substrate 200 can adopt low-temperature polysilicon technology, metal oxide technology, or amorphous silicon technology, which is not limited herein.

In the present embodiment, luminescent material of the light-emitting device layer 300 of the display panel 100 can be processed by vapor-deposition or inkjet printing, which is not limited herein. A pixel definition layer formed by a vapor-deposition method of is a non-hydrophobic pixel definition layer, and the pixel definition layer formed by the inkjet printing method is a hydrophobic pixel definition layer.

In the present embodiment, light emitted from the light-emitting device layer 300 is white light.

In the present embodiment, the light-emitting device layer 300 includes the anode layer 310, the luminescent material layer 320, and the cathode layer 330. Please refer to FIG. 1 and FIG. 2 for details. The cathode layer 330 is disposed away from the array substrate 200. The anode layer 310 is electrically connected to the source-drain layer of the array substrate 200.

S20, forming the color filter layer 400 on the first substrate 401, wherein the color filter layer includes the color resists 410, the light-shielding layer arranged between two adjacent color resists 410, and the auxiliary electrodes 430 arranged on the light-shielding layer.

In the present embodiment, the light-shielding layer is arranged continuously or at intervals.

In the present embodiment, a color of each of the color resists 410 is one of red, blue, or green, which is not limited herein.

In the present embodiment, any two of the auxiliary electrodes 430 are disposed with a spaced insulation.

In the present embodiment, the light-shielding layer is made of a black matrix.

In the present embodiment, the step of forming the color resists 410 and the light-shielding layer arranged between two adjacent color resists 410 includes:

S21, forming a black matrix layer on the first substrate 401;

S22, forming a pattern of a plurality of openings on the black matrix layer through a patterning process to form the light-shielding layer; and

S23, forming the color resists 410 in the openings.

In the present embodiment, the step of forming the color resists 410 and the light-shielding layer arranged between two adjacent color resists 410 includes:

S21, forming a color resist layer on the first substrate 401;

S22, forming the plurality of color resists 410 arranged at intervals from the color resist layer through a patterning process;

S23, forming the black matrix layer on the first substrate 401; and

S24, forming the light-shielding layer from the black matrix layer through a patterning process, wherein the light-shielding layer is arranged between two adjacent color resists 410.

In the present embodiment, the step of forming the light-shielding layer and the auxiliary electrodes 430 includes below.

S201, forming the plurality of first sub light-shielding units 421 on the first substrate 401.

In the present embodiment, the first sub light-shielding units 421 are made of a black matrix.

S202, forming the plurality of auxiliary electrodes 430 on the first sub light-shielding units 421.

In the present embodiment, the resistance value of the auxiliary electrodes 430 close to the center of the display panel 100 is less than the resistance value of the auxiliary electrodes 430 away from the center of the display panel 100. The more severe the voltage drop near the center of the display panel 100, the worse the display effect. The auxiliary electrodes 430 are further electrically connected to an external field, and an external field voltage is given to the auxiliary electrodes during display. The auxiliary electrodes 430 will also have resistance while increasing the voltage; hence, the resistance value of the auxiliary electrodes 430 closer to the center of the display panel 100 is smaller, so that a voltage drop can be better reduced, thereby improving the display effect. The auxiliary electrodes 430 have an effect of reducing the voltage drop, as well as maintaining a step effect between the color filter layer 400 and the array substrate 200 to protect the display panel 100.

In the present embodiment, a thickness of each of the auxiliary electrodes 430 close to the center of the display panel 100 is less than a thickness of each of the auxiliary electrodes 430 away from the center of the display panel 100. Correspondingly, a thickness of the light-shielding layer corresponding to the auxiliary electrodes 430 close to the center of the display panel 100 is greater than a thickness of the light-shielding layer corresponding to the auxiliary electrodes 430 away from the center of the display panel 100. A sum of the thicknesses of any set of one of the auxiliary electrodes 430 and its corresponding the light-shielding layer is same, in a bid to ensure that the auxiliary electrodes 430 and the cathode layer 330 are electrically connected tightly. The more severe the voltage drop near the center of the display panel 100, the worse the display effect. Therefore, the closer to the center of the display panel 100, the smaller the thickness of the auxiliary electrodes 430, and the smaller the resistance value of the auxiliary electrodes 430, which can better reduce the voltage drop, thereby improving the display effect.

In the present embodiment, a contact area of the auxiliary electrodes 430 close to the center of the display panel 100 and the cathode layer 330 is greater than a contact area of the auxiliary electrodes 430 away from the center of the display panel 100 and the cathode layer 330. For details, please refer to FIG. 1 and FIG. 2. The more severe the voltage drop near the center of the display panel 100, the worse the display effect. Therefore, the closer to the center of the display panel 100, the greater the contact area of the auxiliary electrodes 430 and the cathode layer 330, and the smaller the resistance value of the auxiliary electrodes 430, which can better reduce the voltage drop, thereby improving the display effect.

In the present embodiment, a density of the auxiliary electrodes 430 arranged close to the center of the display panel 100 is greater than a density of the auxiliary electrodes 430 arranged away from the center of the display panel 100. Please refer to FIG. 1 and FIG. 2 for details. The more severe the voltage drop near the center of the display panel 100, the worse the display effect. Therefore, the closer to the center of the display panel 100, the greater the density of the auxiliary electrodes 430, and the higher the voltage added to the center display area, which can better reduce the voltage drop, thereby improving the display effect.

In the present embodiment, on a first cross-section, an area of one of the auxiliary electrodes 430 away from the color filter layer 400 is greater than an area of one of the auxiliary electrodes 430 close to the color filter layer 400. The first cross-section is parallel to the display panel 100. Please refer to FIG. 1 and FIG. 2 for details. By increasing the contact area between a single auxiliary electrode 430 and the cathode layer 330 and reducing the resistance value of the single auxiliary electrode 430, the voltage drop can be better reduced and the display effect is improved.

In the present embodiment, material of the auxiliary electrodes 430 is metal, or one of a transparent conductive film or a flexible electrode. Meanwhile, the flexible electrode not only improves the voltage drop close to the center of the display and improves the display effect, but can also better prevent the cathode layer 330 of the display panel 100 from being damaged when the display panel 100 is squeezed, thereby extending the service life of the display panel 100.

S30, aligning and bonding the color filter layer 400 and the light-emitting device layer 300, wherein the auxiliary electrodes 430 are electrically connected to the cathode layer 330 of the light-emitting device layer 300.

The present application provides auxiliary electrodes electrically connected to the cathode layer on the light-shielding layer, and the step effect between the color filter layer and the array substrate is achieved by using the auxiliary electrodes, thereby reducing the voltage drop of the electrode close to the center of the display, improving the uniformity of display brightness, and enhancing the user's visual effects.

### Fourth Embodiment

Please refer to FIG. 1 to FIG. 3. The present embodiment is same as or similar to the third embodiment, except that:

the step of forming the light-shielding layer and the auxiliary electrodes 430 includes:

S201, forming the first light-shielding unit on the first substrate 401;

S202, forming the second light-shielding unit on the first light-shielding unit; and

S203, forming the plurality of auxiliary electrodes 430 on the second light-shielding unit.

In the present embodiment, the step of forming the second light-shielding unit includes:

forming the plurality of second sub light-shielding units 422 on the first light-shielding unit.

A density of the second sub light-shielding units 422 arranged close to the center of the display panel 100 is greater than a density of the second sub light-shielding units 422 arranged away from the center of the display panel 100. Please refer to FIG. 2 for details. The second light-shielding units have a step effect between the color filter layer 400 and the array substrate 200 to protect the display panel 100, and can also be used as a carrier on a side of the auxiliary electrodes 430 to facilitate positioning of the auxiliary electrodes 430 and tight electrical connection of the auxiliary electrodes 430 to the cathode layer 330.

In the present embodiment, the step of forming the first light-shielding unit includes:

forming the plurality of first sub light-shielding units 421 on the first substrate 401.

In the present embodiment, the auxiliary electrodes 430 are formed on any of the first sub light-shielding units 421, and the auxiliary electrodes 430 are formed on the second sub light-shielding units 422. The display panel can have more auxiliary electrodes 430 by adopting the above structure in a direction away from the center of the display, which has more compensation voltages with different voltages, thereby making the display more uniform.

In the present embodiment, the auxiliary electrodes 430 are formed on any of the second sub light-shielding units 422. A part of the second sub light-shielding units 422 has no auxiliary electrode, which can provide more step differences and better protection of the display panel.

In the present embodiment, a thickness of the light-shielding layer is greater than a thickness of the color resists 410. The light-shielding layer and/or the first sub light-shielding units 421 and/or the second sub light-shielding units 422 are overlapped on the color resists 410. Please refer to FIG. 1 and FIG. 2 for details. While the light-shielding layer serves as a carrier for the auxiliary electrodes 430, this structural arrangement can also prevent the mixing of light of various colors, which improves the purity of the display color gamut and improves the display effect.

In the present embodiment, the thickness of the color resists 410 is greater than the thickness of the first light-shielding unit. The color resists 410 are overlapped on the first light-shielding unit. The thickness of the color resists 410 is less than a sum of the thicknesses of the first light-shielding unit and the second light-shielding unit. This structural arrangement can maximize the display aperture ratio, the display brightness is increased, and the display effect is improved.

In the present embodiment, the thickness of the color resists 410 is equal to the thickness of the first light-shielding unit. This structural arrangement can improve the display aperture ratio and increase the display brightness, while also preventing the mixing of light of various colors, thereby improving the purity of the display color gamut and improving the display effect.

The present embodiment, through providing auxiliary electrodes electrically connected to the cathode layer on the light-shielding layer and in cooperation with light-shielding units having different heights, reduces the voltage drop of the electrode close to the center of the display, thereby improving uniformity of the display brightness and enhancing the user's visual effect.

In summary, the present application discloses a display panel and a manufacturing method thereof. The display panel includes an array substrate, a light-emitting device layer arranged on the array substrate, and a color filter layer arranged on the light-emitting device layer. The color filter layer includes a plurality of color resists, a light-shielding layer arranged between two adjacent color resists, and a plurality of auxiliary electrodes arranged on the light-shielding layer; wherein the auxiliary electrodes are electrically connected to a cathode layer of the light-emitting device layer. The present application, through providing auxiliary electrodes electrically connected to the cathode layer on the light-shielding layer and in cooperation with light-shielding units having different heights, reduces the voltage drop of the electrode close to the center of the display, thereby improving uniformity of the display brightness and enhancing the user's visual effect.

It can be understood that for a person of ordinary skill in the art, equivalent replacements or changes can be made according to the technical solution of the present application and its inventive concept, and all these changes or replacements should fall within the protection scope of the claims attached to the present application.

What is claimed is:

1. A display panel, comprising an array substrate, a light-emitting device layer disposed on the array substrate, and a color filter layer disposed on the light-emitting device layer;
wherein the color filter layer comprises a plurality of color resists, a light-shielding layer arranged between two adjacent color resists, and a plurality of auxiliary electrodes disposed on the light-shielding layer; and
wherein the auxiliary electrodes are electrically connected to a cathode layer of the light-emitting device layer.

2. The display panel according to claim 1, wherein a resistance value of one of the auxiliary electrodes close to a center of the display panel is less than a resistance value of one of the auxiliary electrodes away from the center of the display panel.

3. The display panel according to claim 2, wherein a contact area of one of the auxiliary electrodes close to the center of the display panel and the cathode layer is greater than a contact area of one of the auxiliary electrodes away from the center of the display panel and the cathode layer.

4. The display panel according to claim 2, wherein a density of the auxiliary electrodes close to the center of the display panel is greater than a density of the auxiliary electrodes away from the center of the display panel.

5. The display panel according to claim 2, wherein a thickness of each of the auxiliary electrodes close to the center of the display panel is less than a thickness of each of the auxiliary electrodes away from the center of the display panel.

6. The display panel according to claim 1, wherein the light-shielding layer further comprises a first light-shielding unit and a second light-shielding unit arranged on the first light-shielding unit;
wherein the second light-shielding unit comprises a plurality of second sub light-shielding units; and
wherein the auxiliary electrodes are arranged on the second sub light-shielding units, and a density of the second sub light-shielding units close to the center of the display panel is greater than a density of the second sub light-shielding units away from the center of the display panel.

7. The display panel according to claim 6, wherein the auxiliary electrodes are arranged on any of the first sub light-shielding units, and are arranged on the second sub light-shielding units.

8. The display panel according to claim 6, wherein a thickness of each of the color resists is greater than a thickness of the first light-shielding unit, and the color resists are overlapped on the first light-shielding unit.

9. The display panel according to claim 1, wherein a thickness of the light-shielding layer is greater than a thickness of each of the color resists, and the light-shielding layer is overlapped on the color resists.

10. The display panel according to claim 1, wherein a thickness of the light-shielding layer is equal to a thickness of each of the color resists.

11. The display panel according to claim 1, wherein material of the auxiliary electrodes is one of a transparent conductive film or a flexible electrode.

12. A method of manufacturing a display panel, comprising:
forming a light-emitting device layer on an array substrate;
forming a color filter layer on a first substrate, wherein the color filter layer comprises a plurality of color resists, a light-shielding layer arranged between two adjacent color resists, and a plurality of auxiliary electrodes arranged on the light-shielding layer; and
aligning and bonding the color filter layer and the light-emitting device layer, wherein the auxiliary electrodes are electrically connected to a cathode layer of the light-emitting device layer.

13. The method of manufacturing the display panel according to claim 12, wherein a step of forming the light-shielding layer and the auxiliary electrodes comprises:
forming a first light-shielding unit on the first substrate;
forming a second light-shielding unit on the first light-shielding unit; and
forming the auxiliary electrodes on the second light-shielding unit;
wherein the second light-shielding unit comprises a plurality of second sub light-shielding units, and a density of the second sub light-shielding units close to a center of the display panel is greater than a density of the second sub light-shielding units away from the center of the display panel.

14. The method of manufacturing the display panel according to claim 13, wherein the auxiliary electrodes are arranged on any of the first sub light-shielding units, and are arranged on the second sub light-shielding units.

15. The method of manufacturing the display panel according to claim 13, wherein a thickness of each of the color resists is greater than a thickness of the first light-shielding unit, and the color resists are overlapped on the first light-shielding unit.

16. The method of manufacturing the display panel according to claim 12, wherein a resistance value of one of the auxiliary electrodes close to a center of the display panel is less than a resistance value of one of the auxiliary electrodes away from the center of the display panel.

17. The method of manufacturing the display panel according to claim 15, wherein a contact area of one of the auxiliary electrodes close to the center of the display panel and the cathode layer is greater than a contact area of one of the auxiliary electrodes away from the center of the display panel and the cathode layer.

18. The method of manufacturing the display panel according to claim 12, wherein a thickness of the light-shielding layer is greater than a thickness of each of the color resists, and the light-shielding layer is overlapped on the color resists.

19. The method of manufacturing the display panel according to claim 12, wherein a thickness of the light-shielding layer is equal to a thickness of each of the color resists.

20. The method of manufacturing the display panel according to claim 12, wherein material of the auxiliary electrodes is one of a transparent conductive film or a flexible electrode.
